(19) United States
(12) Patent Application Publication
(10) Pub. No.: US 2025/0028867 A1
(43) Pub. Date: Jan. 23, 2025

(54) SYSTEM AND METHOD FOR RECOMMENDING DESIGN ALTERNATIVES BASED ON RESPONSES TO SEMANTIC PROMPTS

(71) Applicant: TOYOTA RESEARCH INSTITUTE, INC., Los Altos, CA (US)

(72) Inventors: Ananya NANDY, Fremont, CA (US); Shabnam HAKIMI, San Francisco, CA (US); Matthew H. KLENK, San Francisco, CA (US); Yin-Ying CHEN, San Jose, CA (US)

(73) Assignees: TOYOTA RESEARCH INSTITUTE, INC., Los Altos, CA (US); TOYOTA JIDOSHA KABUSHIKI KAISHA, Aichi-Ken (JP)

(21) Appl. No.: 18/409,642

(22) Filed: Jan. 10, 2024

Related U.S. Application Data
(60) Provisional application No. 63/527,975, filed on Jul. 20, 2023.

(51) Int. Cl. G06F 30/12; G06F 40/30

(52) U.S. Cl. CPC G06F 30/12; G06F 40/30

(57) ABSTRACT

A method for a physical design tool to recommend design alternatives based on responses to semantic prompts is described. The method includes identifying first design action patterns elicited by a specific semantic prompt that differ across individual designers based on historical data. The method also includes generating sequences of actions with varying similarity to the individual designers to present alternatives to new designers. The method further includes identifying second design action patterns that differ across sematic prompts with different linguistic properties. The method also includes training a behavioral model of each of the individual designers based on responses to the specific semantic prompt, responses to the sematic prompts with the different linguistic properties, and the sequences of actions with the varying similarity. The method further includes displaying the design alternatives recommended to an individual designer based on the behavioral model created for the individual designer.

### CROSS-REFERENCE TO RELATED APPLICATION

The present application claims the benefit of U.S. Provisional Patent Application No. 63/527,975, filed Jul. 20, 2023, and titled “SYSTEM AND METHOD FOR RECOMMENDING DESIGN ALTERNATIVES BASED ON RESPONSES TO SEMANTIC PROMPTS,” the disclosure of which is expressly incorporated by reference herein in its entirety.

### BACKGROUND

### Field

Certain aspects of the present disclosure generally relate to machine assisted design and, more particularly, to a system and method for recommending design alternatives based on responses to semantic prompts.

### Background

Visual content creators may utilize image curation tools to provide an online platform for creating and highlighting their creative work. For example, image curation tools such as PINTEREST® and BEHANCE® are the de facto standard tools used by designers to inspire their work. Nevertheless, exploring a design space involves a manual and aimless process, which is not provided by these image creation tools. In practice, visual content creators first begin their creative process (e.g., concept sketches) by aimlessly searching or scrolling through images in diverse topics (e.g., fashion, architecture, product design, etc.). This searching/scrolling process is followed by iteratively narrowing down the topic, scope, and focus of the search as the visual content creators increase the fidelity of their designs.

A visual content creation tool for augmenting the visual content creation process using, for example, an artificial intelligence (AI) design assistant that recommends design alternatives based on responses to semantic prompts, is desired.

### SUMMARY

A method for a physical design tool to recommend design alternatives based on responses to semantic prompts is described. The method includes identifying first design action patterns elicited by a specific semantic prompt that differ across individual designers based on historical data. The method also includes generating sequences of actions with varying similarity to the individual designers to present alternatives to new designers. The method further includes identifying second design action patterns that differ across sematic prompts with different linguistic properties. The method also includes training a behavioral model of each of the individual designers based on responses to the specific semantic prompt, responses to the sematic prompts with the different linguistic properties, and the sequences of actions with the varying similarity. The method further includes displaying the design alternatives recommended to an individual designer based on the behavioral model created for the individual designer.

A non-transitory computer-readable medium having program code recorded thereon for a physical design tool to recommend design alternatives based on responses to semantic prompts is described. The program code is executed by a processor. The non-transitory computer-readable medium includes program code to identify first design action patterns elicited by a specific semantic prompt that differ across individual designers based on historical data. The non-transitory computer-readable medium also includes program code to generate sequences of actions with varying similarity to the individual designers to present alternatives to new designers. The non-transitory computer-readable medium further includes program code to identify second design action patterns that differ across sematic prompts with different linguistic properties. The non-transitory computer-readable medium also includes program code to train a behavioral model of each of the individual designers based on responses to the specific semantic prompt, responses to the sematic prompts with the different linguistic properties, and the sequences of actions with the varying similarity. The non-transitory computer-readable medium further includes program code to display the design alternatives recommended to an individual designer based on the behavioral model created for the individual designer.

A system for a physical design tool to recommend design alternatives based on responses to semantic prompts is described. The system includes a first design action pattern identification module to identify first design action patterns elicited by a specific semantic prompt that differ across individual designers based on historical data. The system also includes an action sequence module to generate sequences of actions with varying similarity to the individual designers to present alternatives to new designers. The system further includes a second design action pattern identification module to identify second design action patterns that differ across sematic prompts with different linguistic properties. The system also includes a behavior model training module to train a behavioral model of each of the individual designers based on responses to the specific semantic prompt, responses to the sematic prompts with the different linguistic properties, and the sequences of actions with the varying similarity. The system further includes a design alternative display module to display the design alternatives recommended to an individual designer based on the behavioral model created for the individual designer.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

The features, nature, and advantages of the present disclosure will become more apparent from the detailed description set forth below when taken in conjunction with the drawings in which like reference characters identify correspondingly throughout.

FIG. 1 illustrates an example implementation of designing a neural network using a system-on-a-chip (SOC) of a visual content creation system, in accordance with aspects of the present disclosure.

FIG. 2 is a block diagram illustrating an exemplary software architecture that may modularize artificial intelligence (AI) functions for a visual content design system, according to aspects of the present disclosure.

FIG. 3 is a diagram illustrating a hardware implementation for a visual content design system, according to aspects of the present disclosure.

FIG. 4 is a block diagram illustrating a visual content design recommendation system, according to various aspects of the present disclosure.

FIG. 5 is a process flow diagram illustrating a method for recommending design alternatives based on responses to semantic prompts, according to aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts.

Based on the teachings, one skilled in the art should appreciate that the scope of the present disclosure is intended to cover any aspect of the present disclosure, whether implemented independently of or combined with any other aspect of the present disclosure. For example, an apparatus may be implemented, or a method may be practiced using any number of the aspects set forth. In addition, the scope of the present disclosure is intended to cover such an apparatus or method practiced using other structure, functionality, or structure and functionality in addition to, or other than the various aspects of the present disclosure set forth. It should be understood that any aspect of the present disclosure disclosed may be embodied by one or more elements of a claim.

Although particular aspects are described herein, many variations and permutations of these aspects fall within the scope of the present disclosure. Although some benefits and advantages of the preferred aspects are mentioned, the scope of the present disclosure is not intended to be limited to particular benefits, uses, or objectives. Rather, aspects of the present disclosure are intended to be universally applicable to different technologies, system configurations, networks, and protocols, some of which are illustrated by way of example in the figures and in the following description of the preferred aspects. The detailed description and drawings are merely illustrative of the present disclosure, rather than limiting the scope of the present disclosure being defined by the appended claims and equivalents thereof.

Visual content creators may utilize image curation tools to provide an online platform for creating and highlighting their creative work. For example, image curation tools such as PINTEREST® and BEHANCE® are the de facto standard tools used by designers to inspire their work. Nevertheless, exploring a design space involves a manual, somewhat undirected process, which is not supported by these image creation tools. In practice, visual content creators first begin their creative process (e.g., concept sketches) by aimlessly searching or scrolling through images in diverse topics (e.g., fashion, architecture, product design, etc.). This searching/scrolling process is followed by iteratively narrowing down the topic, scope, and focus of the search as the visual content creators increase the fidelity of their designs.

In practice, designers are often given abstract words as semantic prompts (e.g., rugged, sleek, reliable, exciting) and faced with the task of translating these prompts into parameterized 3D designs. Designers may interpret these words in different ways, impacting how the designs are embodied visually throughout the design process. For example, a typical design prompt such as “make this part rugged and pop” could be interpreted differently depending on the designer's domain expertise (e.g., interior vs. exterior design) as well as regional and cultural context (e.g., mass vs. luxury markets).

Presenting people with visual alternatives can enhance design creativity by allowing them to consider options that they may not otherwise think of. Nevertheless, these suggestions must fit into a person's workflow and within a reasonable distance from the person's interpretation of the prompt. For instance, some prompts may elicit prioritization of functional features while others may rely more on aesthetic features. In this case, the user might start their design with actions targeted at optimizing the features that will result in an artifact that can be used in a specific way; starting at this point will shape what they subsequently do—their preferences over aesthetic features will be different as a result of their functional choices. The opposite pattern may emerge for designers who begin with aesthetic choices. Additionally, individuals may have varying preferences over the order and extent to which they implement visual features in response to the semantic prompt. It is therefore necessary to characterize a designer's actions in response to an abstract prompt in order to understand the link between semantic and visual representations of designs and present personalized design alternatives in an automated way. This understanding enables support tool(s) that may present design alternatives in an automated way.

The above example illustrates a process that can be augmented using an artificial intelligence (AI) design assistant that automatically recommends design alternatives based on responses to semantic prompts. Various aspects of the present disclosure enable tracking of design-related actions that users take in the visual domain in response to semantic prompts in order to identify action patterns to predict actions, as well as determine similarities and differences across people and prompts. These aspects of the present disclosure then determine and present alternative action paths that lead to different, but still relevant, designs; these suggested paths can thus augment design creativity. Further, the system learns a representation of the full cycle of design work, connecting an abstract external prompt to a user's intent, the final design artifact, and any subsequent work that will invariably be influenced by this process. With this learned model of the user's psychology and behavior, the system can continually improve its creativity support while also accounting for contextual factors that can influence the design process. These aspects of the present disclosure beneficially improve the adoption of design creativity support tools within companies' design studios by presenting a way to tailor those tools for designers and their contexts.

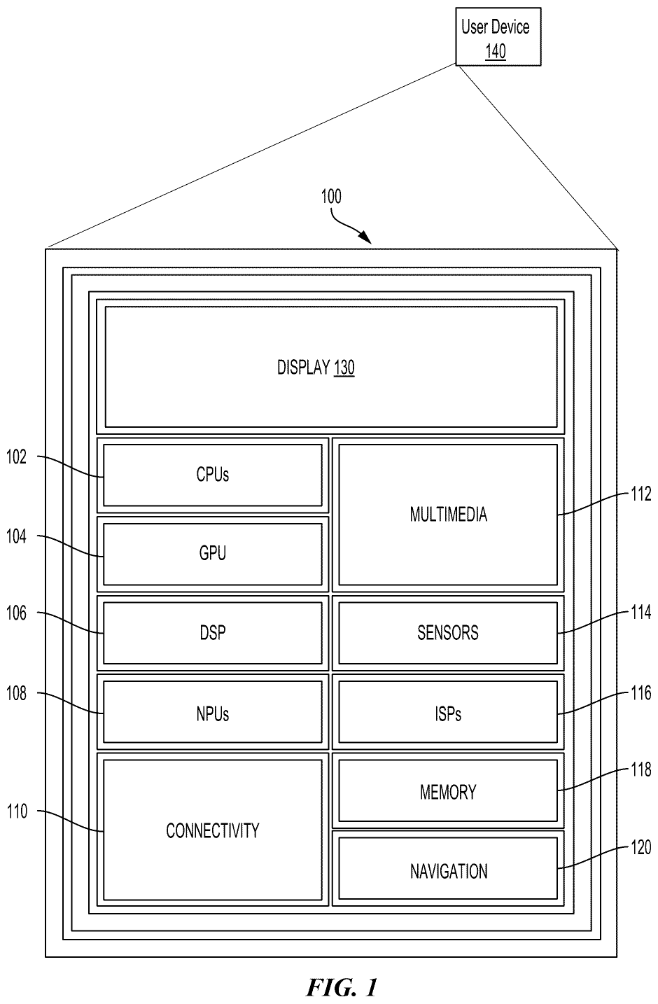

FIG. 1 illustrates an example implementation of the aforementioned system and method for a visual content creation system using a system-on-a-chip (SOC) 100, according to aspects of the present disclosure. The SOC 100 may include a single processor or multi-core processors (e.g., a central processing unit (CPU) 102), in accordance with certain aspects of the present disclosure. Variables (e.g., neural signals and synaptic weights), system parameters associated with a computational device (e.g., neural network with weights), delays, frequency bin information, and task information may be stored in a memory block. The memory block may be associated with a neural processing unit (NPU) 108, a CPU 102, a graphics processing unit (GPU) 104, a digital signal processor (DSP) 106, a dedicated memory block 118, or may be distributed across multiple blocks. Instructions executed at a processor (e.g., CPU 102) may be loaded from a program memory associated with the CPU 102 or may be loaded from the dedicated memory block 118.

The SOC 100 may also include additional processing blocks configured to perform specific functions, such as the GPU 104, the DSP 106, and a connectivity block 110, which may include fourth generation long term evolution (4G LTE) connectivity, unlicensed Wi-Fi connectivity, USB connectivity, Bluetooth® connectivity, and the like. In addition, a multimedia processor 112 in combination with a display 130 may, for example, select a control action, according to the display 130 illustrating a view of a user device.

In some aspects, the NPU 108 may be implemented in the CPU 102, DSP 106, and/or GPU 104. The SOC 100 may further include a sensor processor 114, image signal processors (ISPs) 116, and/or navigation 120, which may, for instance, include a global positioning system. The SOC 100 may be based on an Advanced Risc Machine (ARM) instruction set, RISC-V, or any reduced instruction set computing (RISC) architecture, or the like. In another aspect of the present disclosure, the SOC 100 may be a server computer in communication with a user device 140. In this arrangement, the user device 140 may include a processor and other features of the SOC 100.

In this aspect of the present disclosure, instructions loaded into a processor (e.g., CPU 102) or the NPU 108 may include code to provide a visual content design system for recommending design alternatives based on responses to semantic prompts. The instructions loaded into a processor (e.g., NPU 108) may also include code to identify first design action patterns elicited by a specific semantic prompt that differ across individual designers based on historical data. The instructions loaded into the processor (e.g., NPU 108) may also include code to generate sequences of actions with varying similarity to the individual designers to present alternatives to new designers. The instructions loaded into the processor (e.g., NPU 108) may also include code to identify second design action patterns that differ across sematic prompts with different linguistic properties. The instructions loaded into the processor (e.g., NPU 108) may also include code to train a behavioral model of each of the individual designers based on responses to the specific semantic prompt, responses to the sematic prompts with the different linguistic properties, and the sequences of actions with the varying similarity. The instructions loaded into the processor (e.g., NPU 108) may also include code to display the design alternatives recommended to the individual designer based on the behavioral model created for the individual designer.

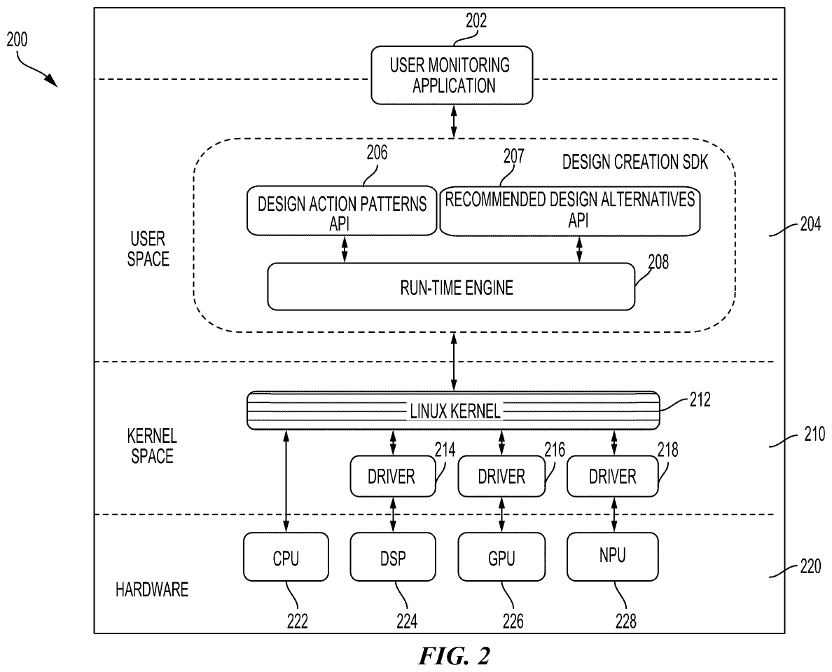

FIG. 2 is a block diagram illustrating a software architecture 200 that may modularize artificial intelligence (AI) functions for a visual content design system, according to aspects of the present disclosure. Using the architecture, a user monitoring application 202 may be designed such that it may cause various processing blocks of an SOC 220 (for example a CPU 222, a DSP 224, a GPU 226, and/or an NPU 228) to perform supporting computations during run-time operation of the user monitoring application 202. FIG. 2 describes the software architecture 200 for a visual content design system. It should be recognized that the visual content design system is not limited to any specific information. According to aspects of the present disclosure, the user monitoring and the visual content design functionality is applicable to any type of information access activity.

The user monitoring application 202 may be configured to call functions defined in a user space 204 that may, for example, provide visual content design services. The user monitoring application 202 may make a request for compiled program code associated with a library defined in a design action pattern application programming interface (API) 206. The design action pattern application API 206 is configured to identify first design action patterns elicited by a specific semantic prompt that differ across individual designers based on historical data. The design action pattern application API 206 is further configured to identify second design action patterns that differ across sematic prompts with different linguistic properties.

In response, compiled program code of a recommended design alternatives API 207 is configured to train a behavioral model of each of the individual designers based on responses to the specific semantic prompt, responses to the sematic prompts with the different linguistic properties, and generated sequences of actions with varying similarity to the individual designers to present alternatives to new designers. Additionally, the recommended design alternatives API 207 is configured to display the design alternatives recommended to the individual designer based on the behavioral model created for the individual designer.

A run-time engine 208, which may be compiled code of a run-time framework, may be further accessible to the user monitoring application 202. The user monitoring application 202 may cause the run-time engine 208, for example, to take actions for recommendations of design alternatives to improve the design of visual content. In response to recommendation of visual content, the run-time engine 208 may in turn send a signal to an operating system 210, such as a Linux Kernel 212, running on the SOC 220. FIG. 2 illustrates the Linux Kernel 212 as software architecture for a visual content creation system. It should be recognized, however, that aspects of the present disclosure are not limited to this exemplary software architecture. For example, other kernels may provide the software architecture to support the visual content design functionality.

The operating system 210, in turn, may cause a computation to be performed on the CPU 222, the DSP 224, the GPU 226, the NPU 228, or some combination thereof. The CPU 222 may be accessed directly by the operating system 210, and other processing blocks may be accessed through a driver, such as drivers 214-218 for the DSP 224, for the GPU 226, or for the NPU 228. In the illustrated example, the deep neural network may be configured to run on a combination of processing blocks, such as the CPU 222 and the GPU 226, or may be run on the NPU 228 if present.

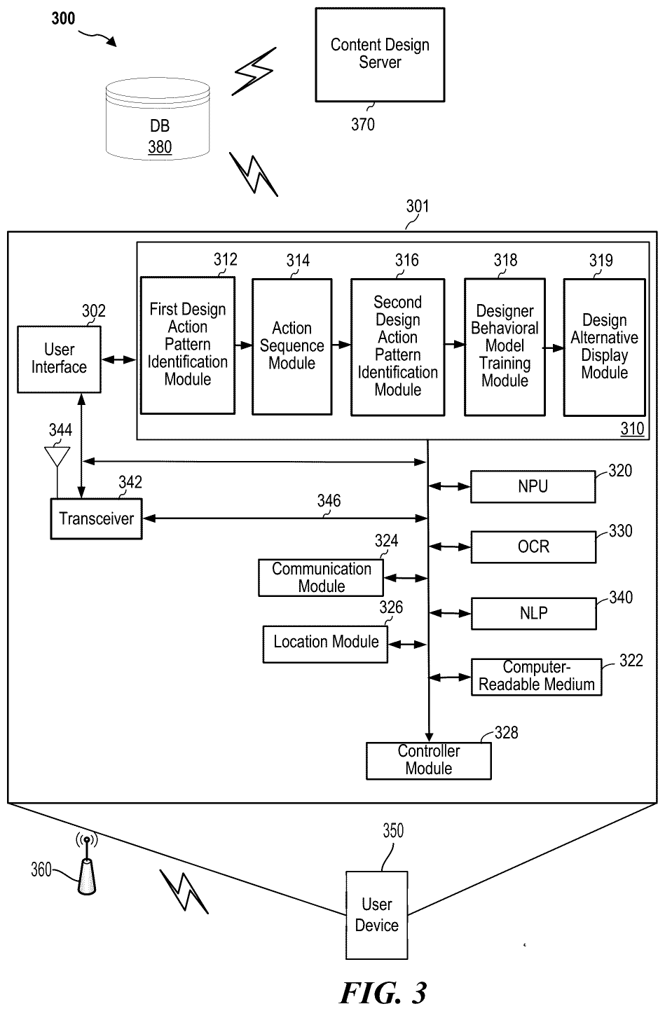

As noted above, existing tools rely on designers to search for inspiration separately (e.g., searching Pinterest) or to passively evaluate completed designs in order to infer their preferred designs (e.g., preference learning). Various aspects of the present disclosure track actions as the designer performs their task (e.g., user actions within a design application such as AutoCAD) to tailor the types of presented alternatives to the individual. It also maintains a model of the user's psychology and behavior that is updated with each interaction. These learned user models allow various aspects of the present disclosure to provide support tailored to both the user and the semantic properties of the design prompt as well as other derived measures (e.g., creativity and relevance to the prompt) within a user's natural workflow. These aspects of the present disclosure maintain a mapping of the user's intent to their actions to the final design, using the actions to infer the intent, predict the final design, and estimate the likelihood that the final design matches the intent. Various aspects of the present disclosure enable tracking of design-related actions that users take in the visual domain in response to semantic prompts in order to identify action patterns to predict actions, as well as determine similarities and differences across people and prompts. These aspects of the present disclosure then determine and present alternative action paths that lead to different, but still relevant, designs, thus augmenting design creativity, for example, as shown in FIG. 3.

FIG. 3 is a diagram illustrating a hardware implementation for a visual content design system 300, according to aspects of the present disclosure. The visual content design system 300 may be configured to enable track of design-related actions that users take in the visual domain in response to semantic prompts in order to identify action patterns to predict actions, as well as determine similarities and differences across people and prompts. The visual content design system 300 then determines and presents alternative action paths that lead to different, but still relevant, designs, thus augmenting design creativity.

The visual content design system 300 includes a user monitoring system 301 and a visual content design server 370 in this aspect of the present disclosure. The user monitoring system 301 may be a component of a user device 350. The user device 350 may be a cellular phone (e.g., a smart phone), a personal digital assistant (PDA), a wireless modem, a wireless communications device, a handheld device, a laptop computer, a cordless phone, a wireless local loop (WLL) station, a tablet, a camera, a gaming device, a netbook, a Smartbook, an Ultrabook, a medical device or equipment, biometric sensors/devices, wearable devices (smart watches, smart clothing, smart glasses, smart wrist bands, smart jewelry (e.g., smart ring, smart bracelet)), an entertainment device (e.g., a music or video device, or a satellite radio), a global positioning system device, or any other suitable device that is configured to communicate via a wireless or wired medium.

The visual content design server 370 may connect to the user device 350 for tracking actions as the designer performs their task (e.g., user actions within a design application such as AutoCAD) to tailor the types of presented alternatives to the individual. For example, the visual content design server 370 may create detailed behavioral models of each designer and their responses to prompts within a natural workflow. Additionally, the visual content design server 370 may also determine and present alternative action paths that lead to different, but still relevant, designs, thus augmenting design creativity.

The user monitoring system 301 may be implemented with an interconnected architecture, represented by an interconnect 346, which may be implemented as a controller area network (CAN). The interconnect 346 may include any number of point-to-point interconnects, buses, and/or bridges depending on the specific application of the user monitoring system 301 and the overall design constraints. The interconnect 346 links together various circuits including one or more processors and/or hardware modules, represented by a user interface 302, a user activity module 310, a neural network processor (NPU) 320, a computer-readable medium 322, a communication module 324, a location module 326, a controller module 328, an optical character recognition (OCR) 330, and a natural language processor (NLP) 340. The interconnect 346 may also link various other circuits such as timing sources, peripherals, voltage regulators, and power management circuits, which are well known in the art, and therefore, will not be described any further.

The user monitoring system 301 includes a transceiver 342 coupled to the user interface 302, the user activity module 310, the NPU 320, the computer-readable medium 322, the communication module 324, the location module 326, the controller module 328, the OCR 330, and NLP 340. The transceiver 342 is coupled to an antenna 344. The transceiver 342 communicates with various other devices over a transmission medium. For example, the transceiver 342 may receive commands via transmissions from a user. In this example, the transceiver 342 may receive/transmit information for the user activity module 310 to/from connected devices within the vicinity of the user device 350.

The user monitoring system 301 includes the NPU 320, the OCR 330, and the NLP 340 coupled to the computer-readable medium 322. The NPU 320, the OCR 330, and NLP 340 performs processing, including the execution of software stored on the computer-readable medium 322 to provide a neural network model for user monitoring and statistical data clarification functionality according to the present disclosure. The software, when executed by the NPU 320, the OCR 330 and the NLP 340, causes the user monitoring system 301 to perform the various functions described for presenting analogies to clarify statistical data presented to the user through the user device 350, or any of the modules (e.g., 310, 324, 326, and/or 328). The computer-readable medium 322 may also be used for storing data that is manipulated by the OCR 330 and the NLP 340 when executing the software to analyze user communications.

The location module 326 may determine a location of the user device 350. For example, the location module 326 may use a global positioning system (GPS) to determine the location of the user device 350. The location module 326 may implement a dedicated short-range communication (DSRC)-compliant GPS unit. A DSRC-compliant GPS unit includes hardware and software to make the user device 350 and/or the location module 326 compliant with the following DSRC standards, including any derivative or fork thereof: EN 12253:2004 Dedicated Short-Range Communication Physical layer using microwave at 5.8 GHz (review); EN 12795:2002 Dedicated Short-Range Communication (DSRC)-DSRC Data link layer: Medium Access and Logical Link Control (review); EN 12834:2002 Dedicated Short-Range Communication Application layer (review); EN 13372:2004 Dedicated Short-Range Communication (DSRC)-DSRC profiles for RTTT applications (review); and EN ISO 14906:2004 Electronic Fee Collection-Application interface.

The communication module 324 may facilitate communications via the transceiver 342. For example, the communication module 324 may be configured to provide communication capabilities via different wireless protocols, such as 5G new radio (NR), Wi-Fi, long term evolution (LTE), 4G, 3G, etc. The communication module 324 may also communicate with other components of the user device 350 that are not modules of the user monitoring system 301. The transceiver 342 may be a communications channel through a network access point 360. The communications channel may include DSRC, LTE, LTE-D2D, mmWave, Wi-Fi (infrastructure mode), Wi-Fi (ad-hoc mode), visible light communication, TV white space communication, satellite communication, full-duplex wireless communications, or any other wireless communications protocol such as those mentioned herein.

The user monitoring system 301 also includes the OCR 330 and the NLP 340 to automatically detect multiple objects in an image displayed on the user's workspace. The user monitoring system 301 may follow a process to detect and determine whether the user accesses creative content. When the user curates images, the user monitoring system 301 utilizes the OCR 330 and/or the NLP 340 to analyze designs of detected objects in the image displayed on the user's workspace.

The user activity module 310 may be in communication with the user interface 302, the NPU 320, the computer-readable medium 322, the communication module 324, the location module 326, the controller module 328, the OCR 330, the NLP 340, and the transceiver 342. In one configuration, the user activity module 310 monitors communications from the user interface 302. The user interface 302 may monitor user communications to and from the communication module 324. According to aspects of the present disclosure, the OCR 330 and the NLP 340 automatically detect images displayed on the user's workspace and may use computer vision object detection and instance segmentation techniques to automatically detect the objects in the image to enable design action pattern analysis to enable determination of design alternatives for a user.

As shown in FIG. 3, the user activity module 310 includes a first design action pattern identification module 312, an action sequence module 314, a second design action pattern identification module 316, a designer behavior model training module 318, and a design alternative display module 319. The first design action pattern identification module 312, the action sequence module 314, the second design action pattern identification module 316, and the designer behavior model training module 318 may be components of a same or different artificial neural network, such as a deep convolutional neural network (CNN). The user activity module 310 is not limited to a CNN. The user activity module 310 monitors and analyzes designs displayed on the user's workspace from the user interface 302.

This configuration of the user activity module 310 includes the first design action pattern identification module 312 configured to identify first design action patterns elicited by a specific semantic prompt that differ across individual designers based on historical data. For example, this data include the design action pattern of designers from different backgrounds as they create a design in response to a specific sematic prompt. These design action patterns may include both large changes to the design such as their function or overall visual representation, as well as changes to smaller details such as size, material, and color.

In various aspects of the present disclosure, the user activity module 310 includes an action sequence module 314 configured to generate sequences of actions with varying similarity to the individual designers to present alternatives to new designers. The action sequence module 314 generates alternatives for presentation through the user interface 302 as visual outcomes of the action sequences; the alternate action sequences themselves may also be revealed to help the user understand their own process. In these aspects of the present disclosure, outcomes derived by the action sequence module 314 from one action might include a single change, while those that involve longer sequences may involve several changes. The timing of presenting these alternatives will be informed by the individual's actions. For example, alternatives with large changes may be presented through the user interface 302 when the users' actions indicate exploration across function or a larger visual structure.

In this example, the user activity module 310 also includes the second design action pattern identification module 316 configured to identify second design action patterns that differ across sematic prompts with different linguistic properties. The second design action patterns differ across semantic prompts with different linguistic properties (e.g., imageability, frequency of use within the context, diversity of meanings, etc.) within different contexts (e.g., to design cars, chairs, etc.). These design action patters may include both large changes to the design such as their function or overall visual representation, as well as changes to smaller details such as size, material, and color. Rollback actions (e.g., undo an action of resizing) are allowed and are tracked, where these logs may be used to create negative data for training a model to generate alternatives.

In some aspects of the present disclosure, the first design action pattern identification module 312 and the second design action pattern identification module 316 use a tuned natural language processing algorithm (e.g., using the NLP 340) to determine higher-level words from a lexical ontology of designs displayed on the user's workspace. The first design action pattern identification module 312 and the second design action pattern identification module 316 may be implemented using a tuned natural language processing algorithm, such as a lexical ontology approach and/or sentiment analysis. In some aspects of the present disclosure, the first design action pattern identification module 312 and the second design action pattern identification module 316 use the OCR 330 and the NLP 340 to identify patterns of actions that differ across prompts with different linguistic properties and specific semantic prompts. For example, first design action pattern identification module 312 and the second design action pattern identification module 316 may be implemented using computer vision-based object detection and instance segmentation and/or a natural language processor. This may include analyzing a designer's workspace for design-related actions.

In various aspects of the present disclosure, sequences of actions would be generated in relation to the prompt type in addition to the individual. The user may be provided information about the linguistic properties of the prompt and related words that may vary the generated action sequences. As shown in FIG. 3, the user activity module 310 includes the designer behavior model training module 318 configured to train a behavioral model of each of the individual designers based on responses to the specific semantic prompt, responses to the sematic prompts with the different linguistic properties, and the sequences of actions with the varying similarity. Thus, aspects of the present disclosure create detailed behavioral models of each designer and their responses to prompts within a natural workflow.

Additionally, the user activity module 310 includes the design alternative display module 319 that is configured to display the design alternatives recommended to the individual designer based on the behavioral model created for the individual designer. For example, the design alternative display module 319 may operates by displaying alternate action sequences to assist the individual designer in understand their own process.

In some aspects of the present disclosure, the visual content design system 300 tracks actions as the designer performs their task (e.g., user actions within a design application such as AutoCAD) to tailor the types of presented alternatives to the individual. In these aspects of the present disclosure, the visual content design system 300 creates detailed behavioral models for each designer and their responses to prompts within a natural workflow. The visual content design system 300 enables tracking of design-related actions that designers take in the visual domain in response to semantic prompts in order to identify action patterns to predict actions, as well as determine similarities and differences across designers and prompts. The visual content design system 300 then determines and presents alternative action paths that lead to different, but still relevant, designs, thus augmenting design creativity.

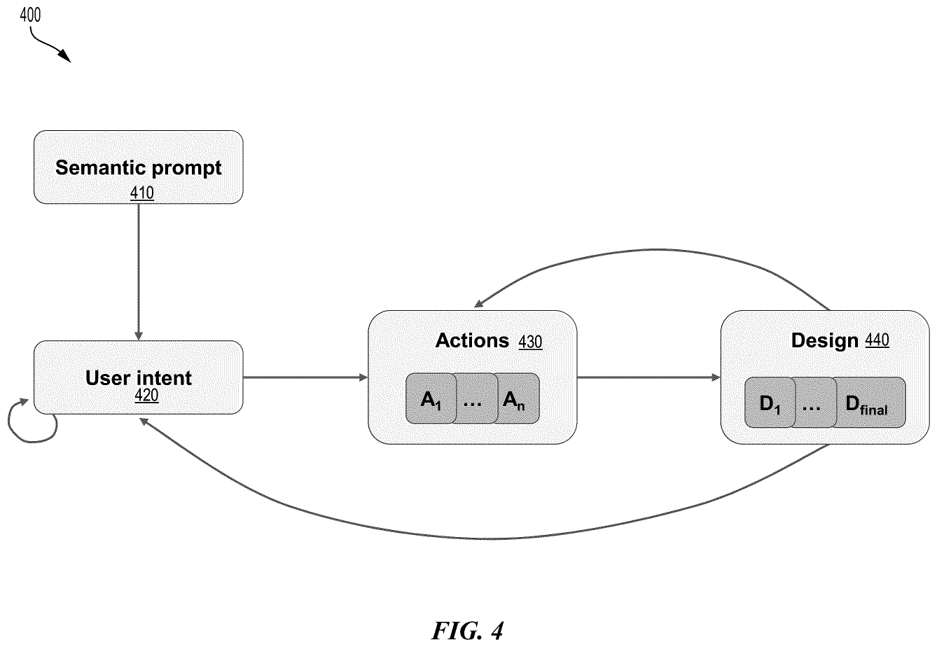

In some aspects of the present disclosure, the user activity module 310 may be implemented and/or work in conjunction with the visual content design server 370. In one configuration, a database (DB) 380 stores data related to designs of images/objects as well as previously design images/objects, which may be displayed as output through the user interface 302. In some aspects of the present disclosure, the visual content design system 300 may be implemented as a web browser plugin. In other aspects of the present disclosure, the visual content design server 370 provides an offline application that scans content viewed through the user interface 302. In other aspects of the present disclosure, the visual content design system 300 may be implemented as a mobile application that augments the visual content design process by recommending design alternatives based on responses to semantic prompts into the user interface 302, for example, as shown in FIG. 4.

FIG. 4 is a block diagram illustrating a visual content design recommendation system, according to various aspects of the present disclosure. As shown in FIG. 4, a visual content design recommendation system 400 illustrates a process that can be augmented using an artificial intelligence (AI) design assistant (e.g., design 440) that automatically recommends design alternatives (D₁, D₂, . . . , D_{final}) based on responses to semantic prompts 410. Various aspects of the present disclosure enable tracking of design-related, actions 430 (e.g., A₁, A₂, . . . , Aₙ) that users take in the visual domain in response to semantic prompts of user intent 420 in order to identify action patterns to predict actions, as well as determine similarities and differences across people and prompts.

As shown in FIG. 4, the visual content design recommendation system 400 tracks the actions (e.g., A₁, A₂, . . . , Aₙ) as the designer performs their task (e.g., user actions within a design application such as AutoCAD) to tailor the types of presented alternatives to the individual. Additionally, the visual content design recommendation system 400 maintains a model of the user's psychology and behavior that is updated with each interaction. These learned user models allow the visual content design recommendation system 400 to provide support tailored to both the user and the semantic properties of the design prompt as well as other derived measures (e.g., creativity and relevance to the prompt) within a user's natural workflow. The visual content design recommendation system 400 maintains a mapping of the user intent 420 to their actions 430 to the design 440 (e.g., a final design), using the actions 430 to infer the user intent 420, predict the final design (e.g., D_{final}), and estimate the likelihood that the final design (e.g., D_{final}) matches the user intent 420.

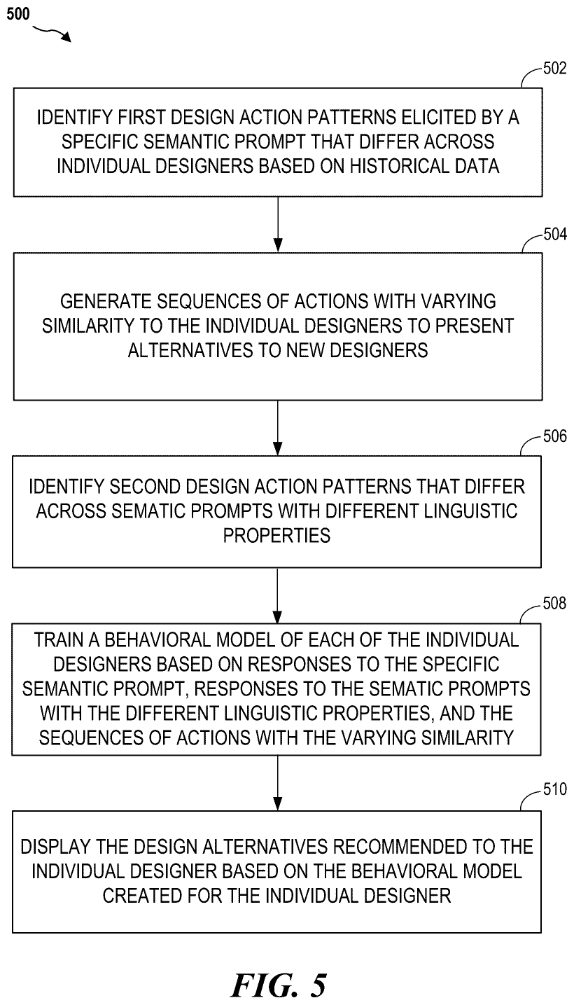

Various aspects of the present disclosure enable tracking of design-related actions that users take in the visual domain in response to semantic prompts 410 in order to identify action patterns to predict actions 430, as well as determine similarities and differences across people and prompts. These aspects of the present disclosure then determine and present alternative action paths that lead to different, but still relevant, designs, thus augmenting design creativity. Further, using a learned model of the user's psychology and behavior, the visual content design recommendation system 400 can continually improve user creativity support while also accounting for contextual factors that can influence the design process. These aspects of the present disclosure beneficially improve the adoption of design creativity support tools within companies' design studios by presenting a way to tailor those tools for designers and their contexts using a process, for example, as shown in FIG. 5.

FIG. 5 is a process flow diagram illustrating a method 500 for a physical design tool to recommend design alternatives based on responses to semantic prompts, according to aspects of the present disclosure. The method 500 begins at block 502, in which first design action patterns are identified that are elicited by a specific semantic prompt that differ across individual designers based on historical data. For example, as shown in FIG. 3, the visual content design system 300 identifies patterns of actions that differ across individuals based on historical data, using a machine-learning or rule-based approach. (That is, the state-action pattern model will be pre-trained on historical data before being further trained on individual user or use case data.) These data include the actions of people from different backgrounds as they create a design in response to semantic prompts with different linguistic properties (e.g., imageability, frequency of use within the context, diversity of meanings, etc.) within different contexts (e.g., to design cars, chairs, etc.). In this example, these actions include both large changes to the design such as their function or overall visual representation, as well as changes to smaller details such as size, material, and color. Such actions may be discrete or continuous in nature. Rollback actions (e.g., undo an action of resizing) are allowed and are tracked, where these logs may be used to create negative data for training a model to generate alternatives, for example, as shown in FIG. 4.

At block 504, generate sequences of actions with varying similarity to the individual designers to present alternatives to new designers. For example, as shown in FIG. 3, the visual content design system 300 generate sequences of actions with varying similarity to the individual to present alternatives to new users. Additionally, alternatives are presented as visual outcomes of the action sequences; the alternate action sequences themselves may also be revealed to help the user understand their own process. In some aspects of the present disclosure, outcomes derived from one action might include a single change, while those that involve longer sequences may involve several changes. In this example, the timing of presenting these alternatives is informed by the individual's actions. For example, alternatives with large changes may be presented only when the users' actions indicate exploration across function or larger visual structure.

At block 506, identify second design action patterns that differ across sematic prompts with different linguistic properties. For example, as shown in FIG. 3, the visual content design system 300 is configured to identify patterns of actions that differ across prompts with different linguistic properties. Then, the visual content design system 300 generates sequences of actions in relation to the prompt type in addition to the individual. Additionally, the user may be provided information about the linguistic properties of the prompt and related words that may vary the generated action sequences. Using this semantic information about the prompt and its close (or far) associates, the system can generate a wider array of potential action sequences, ultimately providing the user with the opportunity to adjust the design to better match their intent, for example, as shown in FIG. 4.

At block 508, a behavioral model of each of the individual designers is trained based on responses to the specific semantic prompt, responses to the sematic prompts with the different linguistic properties, and the sequences of actions with the varying similarity. For example, as shown in FIG. 3, the user activity module 310 includes the designer behavior model training module 318 configured to train a behavioral model of each of the individual designers based on responses to the specific semantic prompt, responses to the sematic prompts with the different linguistic properties, and the sequences of actions with the varying similarity. Thus, aspects of the present disclosure create detailed behavioral models of each designer and their responses to prompts within a natural workflow.

At block 510, display the design alternatives recommended to the individual designer based on the behavioral model created for the individual designer. For example, as shown in FIG. 3, the visual content design system 300 tracks actions as the designer performs their task (e.g., user actions within a design application such as AutoCAD) to tailor the types of presented alternatives to the individual. In these aspects of the present disclosure, the visual content design system 300 creates detailed behavioral models of each designer and their responses to prompts within a natural workflow. The visual content design system 300 enables tracking of design-related actions that users take in the visual domain in response to semantic prompts in order to identify action patterns to predict actions, as well as determine similarities and differences across people and prompts. The visual content design system 300 then determines and presents alternative action paths that lead to different, but still relevant, designs, thus augmenting design creativity.

The various operations of methods described above may be performed by any suitable means capable of performing the corresponding functions. The means may include various hardware and/or software component(s) and/or module(s), including, but not limited to, a circuit, an application-specific integrated circuit (ASIC), or processor. Where there are operations illustrated in the figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Additionally, “determining” may include receiving (e.g., receiving information), accessing (e.g., accessing data in a memory), and the like. Furthermore, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logical blocks, modules and circuits described in connection with the present disclosure may be implemented or performed with a processor configured according to the present disclosure, a digital signal processor (DSP), an ASIC, a field-programmable gate array signal (FPGA) or other programmable logic device (PLD), discrete gate or transistor logic, discrete hardware components, or any combination thereof designed to perform the functions described herein. The processor may be a microprocessor, but, in the alternative, the processor may be any commercially available processor, controller, microcontroller, or state machine specially configured as described herein. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in any form of storage medium that is known in the art. Some examples of storage media that may be used include random access memory (RAM), read-only memory (ROM), flash memory, erasable programmable read-only memory (EPROM), electrically erasable programmable read-only memory (EEPROM), registers, a hard disk, a removable disk, a CD-ROM, and so forth. A software module may comprise a single instruction, or many instructions, and may be distributed over several different code segments, among different programs, and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a device. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may connect a network adapter, among other things, to the processing system via the bus. The network adapter may implement signal processing functions. For certain aspects, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processor may be responsible for managing the bus and processing, including the execution of software stored on the machine-readable media. Examples of processors that may be specially configured according to the present disclosure include microprocessors, microcontrollers, DSP processors, and other circuitry that can execute software. Software shall be construed broadly to mean instructions, data, or any combination thereof, whether referred to as software, firmware, middleware, microcode, hardware description language, or otherwise. Machine-readable media may include, by way of example, RAM, flash memory, ROM, programmable read-only memory (PROM), EPROM, EEPROM, registers, magnetic disks, optical disks, hard drives, or any other suitable storage medium, or any combination thereof. The machine-readable media may be embodied in a computer-program product. The computer-program product may comprise packaging materials.

In a hardware implementation, the machine-readable media may be part of the processing system separate from the processor. However, as those skilled in the art will readily appreciate, the machine-readable media, or any portion thereof, may be external to the processing system. By way of example, the machine-readable media may include a transmission line, a carrier wave modulated by data, and/or a computer product separate from the device, all which may be accessed by the processor through the bus interface. Alternatively, or in addition, the machine-readable media, or any portion thereof, may be integrated into the processor, such as the case may be with cache and/or specialized register files. Although the various components discussed may be described as having a specific location, such as a local component, they may also be configured in several ways, such as certain components being configured as part of a distributed computing system.

The processing system may be configured with one or more microprocessors providing the processor functionality and external memory providing at least a portion of the machine-readable media, all linked together with other supporting circuitry through an external bus architecture. Alternatively, the processing system may comprise one or more neuromorphic processors for implementing the neuron models and models of neural systems described herein. As another alternative, the processing system may be implemented with an ASIC with the processor, the bus interface, the user interface, supporting circuitry, and at least a portion of the machine-readable media integrated into a single chip, or with one or more FPGAs, PLDs, controllers, state machines, gated logic, discrete hardware components, or any other suitable circuitry, or any combination of circuits that can perform the various functions described throughout this present disclosure. Those skilled in the art will recognize how best to implement the described functionality for the processing system depending on the particular application and the overall design constraints imposed on the overall system.

The machine-readable media may comprise a number of software modules. The software modules include instructions that, when executed by the processor, cause the processing system to perform various functions. The software modules may include a transmission module and a receiving module. Each software module may reside in a single storage device or be distributed across multiple storage devices. By way of example, a software module may be loaded into RAM from a hard drive when a triggering event occurs. During execution of the software module, the processor may load some of the instructions into cache to increase access speed. One or more cache lines may then be loaded into a special purpose register file for execution by the processor. When referring to the functionality of a software module below, it will be understood that such functionality is implemented by the processor when executing instructions from that software module. Furthermore, it should be appreciated that aspects of the present disclosure result in improvements to the functioning of the processor, computer, machine, or other system implementing such aspects.

If implemented in software, the functions may be stored or transmitted over as one or more instructions or code on a non-transitory computer-readable medium. Computer-readable media include both computer storage media and communication media, including any medium that facilitates transfer of a computer program from one place to another. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Additionally, any connection is properly termed a computer-readable medium. For example, if the software is transmitted from a website, server, or other remote source using a coaxial cable, fiber optic cable, twisted pair, digital subscriber line (DSL), or wireless technologies such as infrared (IR), radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk, and Blu-ray® disc where disks usually reproduce data magnetically, while discs reproduce data optically with lasers. Thus, in some aspects computer-readable media may comprise non-transitory computer-readable media (e.g., tangible media). In addition, for other aspects, computer-readable media may comprise transitory computer-readable media (e.g., a signal). Combinations of the above should also be included within the scope of computer-readable media.

Thus, certain aspects may comprise a computer program product for performing the operations presented herein. For example, such a computer program product may comprise a computer-readable medium having instructions stored (and/or encoded) thereon, the instructions being executable by one or more processors to perform the operations described herein. For certain aspects, the computer program product may include packaging material.

Further, it should be appreciated that modules and/or other appropriate means for performing the methods and techniques described herein can be downloaded and/or otherwise obtained by a user terminal and/or base station as applicable. For example, such a device can be coupled to a server to facilitate the transfer of means for performing the methods described herein. Alternatively, various methods described herein can be provided via storage means (e.g., RAM, ROM, a physical storage medium such as a CD or floppy disk, etc.), such that a user terminal and/or base station can obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. A method for a physical design tool to recommend design alternatives based on responses to semantic prompts, comprising:
identifying first design action patterns elicited by a specific semantic prompt that differ across individual designers based on historical data;
generating sequences of actions with varying similarity to the individual designers to present alternatives to new designers;
identifying second design action patterns that differ across sematic prompts with different linguistic properties;
training a behavioral model of each of the individual designers based on responses to the specific semantic prompt, responses to the sematic prompts with the different linguistic properties, and the sequences of actions with the varying similarity; and
displaying the design alternatives recommended to an individual designer based on the behavioral model created for the individual designer.

2. The method of claim 1, in which identifying design action patterns elicited by the specific semantic prompt comprises automatically recognizing the design action patterns from the historical data using computer vision-based object detection and instance segmentation and/or a natural language processor.

3. The method of claim 1, in which identifying design action patterns that differ across the sematic prompts comprises using optical character recognition (OCR) block and/or a natural language processor (NLP) to analyze the design action patterns that differ across the sematic prompts with the different linguistic properties.

4. The method of claim 1, further comprising displaying alternate action sequences to assist the individual designer in understanding their own process.

5. The method of claim 1, in which displaying comprising:
displaying, through a user interface, the design alternatives recommended to the individual designer based on design action patterns that differ across the sematic prompts with the different linguistic properties and the design action patterns elicited by the specific semantic prompt that differ across the individual designers based on the historical data; and
displaying the sequences of actions with the varying similarity.

6. The method of claim 1, in which displaying comprises providing the individual designer with information regarding linguistic properties of the specific semantic prompt and related words that may vary generated sequences of design action patterns.

7. The method of claim 1, further comprising:
analyzing a designer's workspace for design-related actions using computer vision-based object detection and instance segmentation and/or a natural language processor;
tracking of the design-related actions that users take in a visual domain in response to semantic prompts in order to identify action patterns to predict actions, as well as determine similarities and differences across designers and prompts; and
determining and presenting alternative action paths that lead to different, but still relevant, designs to augment design creativity based on visual outcomes.

8. The method of claim 7, further comprising predicting, using the behavioral model of the individual designer, the design alternatives within a natural workflow.

9. A non-transitory computer-readable medium having program code recorded thereon for a physical design tool to recommend design alternatives based on responses to semantic prompts, the program code being executed by a processor and comprising:
program code to identify first design action patterns elicited by a specific semantic prompt that differ across individual designers based on historical data;
program code to generate sequences of actions with varying similarity to the individual designers to present alternatives to new designers;
program code to identify second design action patterns that differ across sematic prompts with different linguistic properties;
program code to train a behavioral model of each of the individual designers based on responses to the specific semantic prompt, responses to the sematic prompts with the different linguistic properties, and the sequences of actions with the varying similarity; and
program code to display the design alternatives recommended to an individual designer based on the behavioral model created for the individual designer.

10. The non-transitory computer-readable medium of claim 9, in which the program code to identify design action patterns elicited by the specific semantic prompt comprises program code to automatically recognize the design action patterns from the historical data using computer vision-based object detection and instance segmentation and/or a natural language processor.

11. The non-transitory computer-readable medium of claim 9, in which the program code to identify design action patterns that differ across the sematic prompts comprises program code to use optical character recognition (OCR) block and/or a natural language processor (NLP) to analyze the design action patterns that differ across the sematic prompts with the different linguistic properties.

12. The non-transitory computer-readable medium of claim 9, further comprising program code to display alternate action sequences to assist the individual designer in understanding their own process.

13. The non-transitory computer-readable medium of claim 9, in which the program code to display comprising:
program code to display, through a user interface, the design alternatives recommended to the individual designer based on design action patterns that differ across the sematic prompts with the different linguistic properties and the design action patterns elicited by the specific semantic prompt that differ across the individual designers based on the historical data; and
program code to display the sequences of actions with the varying similarity.

14. The non-transitory computer-readable medium of claim 9, in which the program code to display comprises program code to provide the individual designer with information regarding linguistic properties of the specific semantic prompt and related words that may vary generated sequences of design action patterns.

15. The non-transitory computer-readable medium of claim 9, further comprising:
program code to analyze a designer's workspace for design-related actions using computer vision-based object detection and instance segmentation and/or a natural language processor;
program code to track of the design-related actions that users take in a visual domain in response to semantic prompts in order to identify action patterns to predict actions, as well as determine similarities and differences across designers and prompts; and
program code to determine and presenting alternative action paths that lead to different, but still relevant, designs to augment design creativity based on visual outcomes.

16. The non-transitory computer-readable medium of claim 15, further comprising program code to predict, using the behavioral model of the individual designer, the design alternatives within a natural workflow.

17. A system for a physical design tool to recommend design alternatives based on responses to semantic prompts, the system comprising:
a first design action pattern identification module to identify first design action patterns elicited by a specific semantic prompt that differ across individual designers based on historical data;
an action sequence module to generate sequences of actions with varying similarity to the individual designers to present alternatives to new designers;
a second design action pattern identification module to identify second design action patterns that differ across sematic prompts with different linguistic properties;
a behavior model training module to train a behavioral model of each of the individual designers based on responses to the specific semantic prompt, responses to the sematic prompts with the different linguistic properties, and the sequences of actions with the varying similarity; and
a design alternative display module to display the design alternatives recommended to an individual designer based on the behavioral model created for the individual designer.

18. The system of claim 17, in which the first design action pattern identification module is further to automatically recognize design action patterns from the historical data using computer vision-based object detection and instance segmentation and/or a natural language processor.

19. The system of claim 17, in which the first design action pattern identification module is further to use optical character recognition (OCR) block and/or a natural language processor (NLP) to analyze design action patterns that differ across the sematic prompts with the different linguistic properties.

20. The system of claim 17, in which the design alternative display module is further to provide the individual designer with information regarding linguistic properties of the specific semantic prompt and related words that may vary generated sequences of design action patterns.
